(19) United States
(12) Patent Application Publication
(10) Pub. No.: US 2010/0282313 A1
(43) Pub. Date: Nov. 11, 2010

(54) DYE-SENSITIZED SOLAR CELL USING COMPOSITE SEMICONDUCTOR MATERIAL

(75) Inventors: Shinn-Horng Chen, Kaohsiung (TW); An-I Tsai, Kaohsiung (TW); Chun-Wei Huang, Kaohsiung (TW)

Correspondence Address: SUGHRUE MION, PLLC, 2100 PENNSYLVANIA AVENUE, N.W., SUITE 800, WASHINGTON, DC, 20037, US

(73) Assignee: ETERNAL CHEMICAL CO., LTD., Ksohsiung (TW)

(21) Appl. No.: 12/772,739

(22) Filed: May 3, 2010

(30) Foreign Application Priority Data
May 5, 2009 (TW) 098114940

(51) Int. Cl. H01L 31/0264

(52) U.S. Cl. 136/256; 977/773; 977/932

(57) ABSTRACT

The invention relates to a dye-sensitized solar cell using composite semiconductor materials, said composite semiconductor materials comprising semiconductor material particles and inorganic particulates coated on the surfaces of the semiconductor material particles, wherein the composite semiconductor materials have a surface area in the range from about 15 to about 80 m²/g. Since the composite semiconductor materials used in the present invention have a large surface area, the solar cell according to the present invention can have an increased adsorption amount of photosensitizers without increasing the thickness of the semiconductor material layer, and exhibits increased efficiency.

### FIELD OF THE INVENTION

The present invention relates to a dye-sensitized solar cell (DSSC) using composite semiconductor materials.

### DESCRIPTION OF THE PRIOR ART

With the rapid development in science and economy, energy consumption is greatly increased. The reserve of traditional energy resources, such as petroleum, natural gas, and coal, is in constant decline, and the increasing demand has to be met by other, new sources. Solar energy is environmentally clean, and is thus one of the most important research topics in the field. So far, various types of solar cells have been developed, among which the DSSC is considered to have the greatest potential because of its relatively low cost.

In 1976, the DSSC was developed by the Tsubomura team from Japan by using porous ZnO as an electrode, and the photoelectric conversion efficiency was 2.5%. After the photoelectric conversion efficiency of the DSSC was increased to 7.1-7.9% by the M. Grätzel team from Switzerland in 1991, commercialization became possible. In the DSSC developed by the M. Grätzel team, TiO₂ nanometer crystal grains are coated on an ITO glass as an anode, and a pore structure of the porous film of the TiO₂ nanometer grains is used to adsorb a Ru-complexes photosensitizer (N3 and N719 are used for representation), so as to absorb the visible light. Further, platinum-plated conductive glass is used as a cathode, and an electrolyte provides an oxidation-reduction reaction required by the cell by using an iodide ion (I^{-/}I₃⁻) solution. The structures of N3 and N719 are shown as follows.

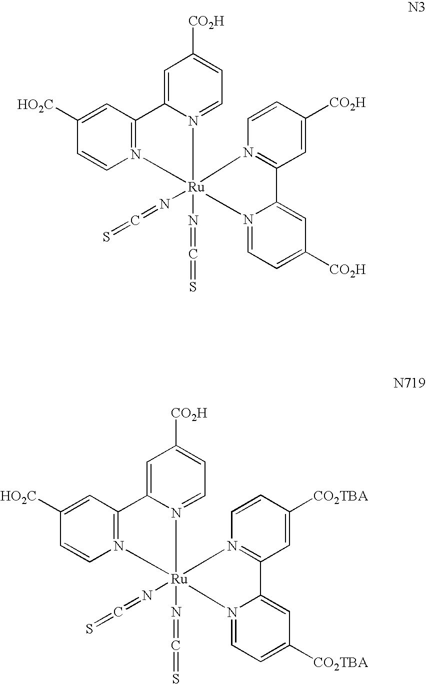

As described above, the DSSC mainly includes five parts, namely, a cathode/anode substrate providing a current flowing path, a semiconductor oxide such as TiO₂ serving as an electron transmission layer, a photosensitizer layer, an electrolyte for transmitting electrons and holes, and a packaging material for protecting and connecting the two electrodes.

Each part of the DSSC affects the efficiency of the whole cell, in which the semiconductor oxide plays an important role. Michael Gratzel disclosed in Inorganic chemistry, vol 44, pp 6841, that the semiconductor oxide particles for scattering the light ray preferably have a particle size from 100 to 400 nm. Further, Michael Gratzel disclosed in U.S. Pat. No. 5,441,827 using semiconductor oxides having two different particle sizes. A first layer adjacent to the conductive layer comprising semiconductor oxide particles having a smaller particle size of about 10 nm to 50 nm is used. This layer is referred to as an adsorbing layer, and mainly functions to provide a surface area for the photosensitizers to be adsorbed thereon. The remaining layer near the electrolyte is referred to as a scattering layer, in which the semiconductor oxide particles have a larger particle size of about 100 nm to 300 nm, and mainly functions to scatter the sun light, thereby increasing the utilization rate of the light source. Takashi Tomita discloses in U.S. Pat. No. 7,312,507 that if two layers of semiconductor oxides having different particle sizes are used, the obstructing effect on the light ray will be too great, so another manner of using two semiconductor oxides having different particle sizes is provided, in which the oxides having different particle sizes are mixed within the thickness of a single layer so as to reduce the obstruction effect on the light ray. However, in this manner, the adsorption amount of the adsorption layer on the photosensitizer is sacrificed.

In addition, the contacting continuity of the semiconductor oxide particles is one of the important factors. The conductive band is continuous because of the continuity of the semiconductor oxide particles. Regarding the material, using the same material is the optimal choice. No matter whether the particle size is small or large, the accumulation of the particles having the same particle size is less compact than the mixing of the particles with different particle sizes. In order to achieve the most compact accumulation, different particle sizes need to be combined.

FIG. 3A shows a semiconductor material layer (12) and a conductive substrate (11) of a conventional DSSC, in which the semiconductor material layer (12) includes semiconductor particles (16) having photosensitizers adsorbed thereon. FIG. 3B is a schematic enlarged view of the semiconductor particle (16) having photosensitizers adsorbed thereon, in which the photosensitizers (15) are adsorbed on a semiconductor material particle (14). As shown in FIG. 3A, a light ray of a light source (13) is incident to the semiconductor material layer (12) through the substrate (11). When passing through the semiconductor material layer (12), the light ray contacts the photosensitizers (15) on a surface of the semiconductor material particle (14), so as to generate a photovoltaic action. When the light ray passes through the semiconductor material layer, because the traveling path is a short straight line, the light ray cannot effectively contact the photosensitizers, thereby making the efficiency of the cell element poor.

### SUMMARY OF THE INVENTION

Accordingly, the present invention is directed to a DSSC, which comprises (a) a first electrode comprising a conductive substrate, a semiconductor material layer, and a photosensitizer, (b) an electrolyte, and (c) a second electrode. The semiconductor material layer includes a composite semiconductor material layer, the composite semiconductor material layer includes composite semiconductor materials, the composite semiconductor materials include first semiconductor material particles and inorganic particulates coated on the surfaces of the first semiconductor material particles, and the composite semiconductor materials have a surface area in a range from about 15 to about 80 m²/g.

As shown in FIG. 4A, the semiconductor material layer of the present invention includes a composite semiconductor material layer (26), and the composite semiconductor material layer includes composite semiconductor materials (27) having photosensitizers adsorbed thereon. FIG. 4B is a schematic enlarged view of the composite semiconductor material (27) having photosensitizers adsorbed thereon. Referring to FIG. 4B, the photosensitizers (15) are adsorbed on the surface of a first semiconductor material particle (25) and on the surfaces of the inorganic particulates (24) of the composite semiconductor material, and the first semiconductor material particle (25) has a different particle size with that of the inorganic particulates (24). Referring to FIG. 4A, it is assumed that a light source (13) is incident to the composite semiconductor material layer (26) of the present invention from a conductive substrate (11), and the light is refracted for several times through the composite semiconductor materials (27) having the photosensitizers adsorbed thereon, such that a light traveling path is lengthened, and the light contacts with the photosensitizer more effectively. Further, the inorganic particulates have a small particle size, thus having a larger surface area, and the inorganic particulates may adsorb more photosensitizers, thereby performing more photovoltaic actions and increasing the efficiency of the cell element.

In other words, the composite semiconductor material layer of the semiconductor material layer of the DSSC according to the present invention has a scattering function, and has a larger surface area so as to greatly increase the amount of the photosensitizers adsorbed thereon, thereby increasing the length of the light path without increasing the thickness of the semiconductor material particle layer, such that the efficiency of the cell element is increased.

### BRIEF DESCRIPTION OF THE DRAWINGS

FIGS. 1 and 2 are each a schematic structural view of a DSSC according to the present invention;

FIG. 3A is a view of the path of a light ray of a conventional DSSC;

FIG. 3B is a schematic enlarged view of a semiconductor particle having photosensitizers adsorbed thereon that is used in the DSSC as shown in FIG. 3A;

FIG. 4A is a view of the path of a light ray of a DSSC according to the present invention; and

FIG. 4B is a schematic enlarged view of a composite semiconductor material having photosensitizers adsorbed thereon that is used in the DSSC according to the present invention.

### DETAILED DESCRIPTION OF THE INVENTION

A semiconductor material layer used by a DSSC according to the present invention includes a composite semiconductor material layer, the composite semiconductor material layer includes composite semiconductor materials, the composite semiconductor materials include first semiconductor material particles and inorganic particulates coated on surfaces of the first semiconductor material particles, and the composite semiconductor materials have a surface area in a range from about 15 to about 80 m²/g. The composite semiconductor material layer can be used as a light scattering layer and a photosensitizer adsorbing layer at the same time. According to an embodiment of the present invention, the composite semiconductor materials have a surface area in a range from about 20 to about 60 m²/g, and a particle size ratio of the inorganic particulates to the first semiconductor material particles is not greater than ½.

The semiconductor material layer used by the DSSC according to the present invention may further include a second semiconductor material layer. The second semiconductor material layer includes a second semiconductor material including second semiconductor material particles having a particle size in a range from 10 nm to 80 nm. When the second semiconductor material layer exists, it may be disposed on a light incident surface or a light exit surface of the composite semiconductor material layer. According to a preferred embodiment of the present invention, the second semiconductor material layer is disposed on the light incident surface of the composite semiconductor material layer.

The first and the second semiconductor material particles used in the present invention are independently selected from the group consisting of titanium oxide, zinc oxide, tin oxide, zirconia, strontium titanate, silicon oxide, indium oxide, zinc sulfide, cadmium selenide, gallium phosphide, cadmium telluride, molybdenum selenide, tungsten selenide, niobium oxide, tungsten oxide, potassium tantalate, cadmium sulfide, and any mixture thereof. Preferably, the first and the second semiconductor material particles used in the present invention are independently selected from the group consisting of titanium oxide, zinc oxide, tin oxide, and any mixture thereof, and more preferably, titanium oxide. According to an embodiment of the present invention, the first semiconductor material particles of the composite semiconductor material used in the present invention have a particle size in a range from 100 nm to 400 nm, and the second semiconductor material particles have a particle size in a range from 10 nm to 80 nm.

The inorganic particulates used in the present invention are selected from the group consisting of titanium oxide, zinc oxide, tin oxide, zirconia, strontium titanate, silicon oxide, indium oxide, zinc sulfide, cadmium selenide, gallium phosphide, cadmium telluride, molybdenum selenide, tungsten selenide, niobium oxide, tungsten oxide, potassium tantalate, cadmium sulfide, calcium phosphate, calcium oxide, and any mixture thereof. Preferably, the inorganic particulates used in the present invention are titanium oxide, zinc oxide, tin oxide or any mixture thereof, and more preferably, titanium oxide.

The composite semiconductor material according to the present invention may be prepared by hydrolyzing a precursor of the inorganic particulates, adding a weak acid for protection, and then combining with the first semiconductor material particles.

According to an embodiment of the present invention, the method for preparing the composite semiconductor material used by the DSSC according to the present invention includes the following steps:

(A) Hydrolyze the precursor (titanium isopropoxide) of the inorganic particulates to obtain a white gel hydrate;

(B) Add a weak acid having a pH value greater than 1 to the hydrate in a reactor, and stir for 10-50 minutes, so as to obtain a weak acid titanium solution;

(C) Add the first semiconductor material particles (TiO₂ particles) to the weak acid titanium solution, make them fully mixed, and stir for 0.5-2 hours under 60-100° C.; and

(D) Rise the temperature to 180-270° C., and react for 8-15 hours under a fixed temperature.

In addition to controlling the hydrolyzing speed under the acidic condition, the weak acid used in Step (B) may prevent the inorganic particulates from being over-aggregated during the crystallization, so as to reduce the generation of the inorganic particulates having a large particle size. If a strong acid was used, the first semiconductor material particles would be significantly dissolved, so a weak acid having a pH value greater than 1 needs to be used. Further, the first semiconductor material particles used in Step (C) have the particle size in a range from 100 nm to 400 nm. In the above-mentioned method, the ratio of the amount of the first semiconductor material particles to that of the precursor of the inorganic particulates can be controlled. For forming inorganic particulates having a less amount and a smaller size on the surface of the first semiconductor material particle, a less amount of the precursor of the inorganic particulates is used, and on the contrary, a more amount is used. The results obtained by using the first semiconductor material particle (titanium oxide) and the precursor (titanium isopropoxide) of the inorganic particulates in different weight ratios are as shown in the following Table 1.

TABLE 1

| | | |
|---|---|---|
| titanium oxide:titanium isopropoxide | 7:3 | 3:7 |
| Surface Area (m²/g) | 20 | 40 |

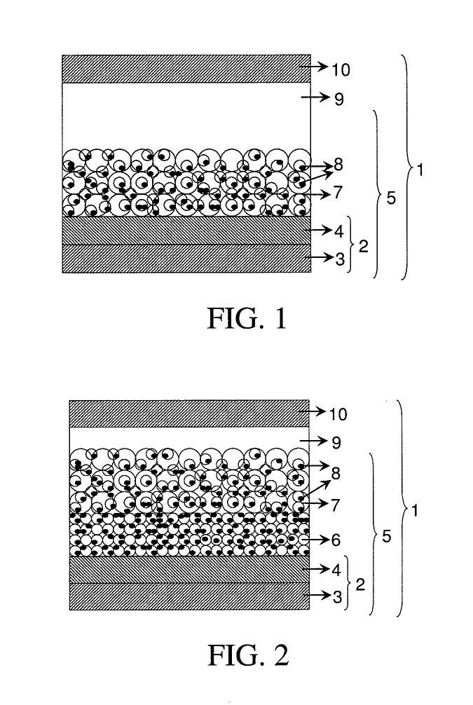

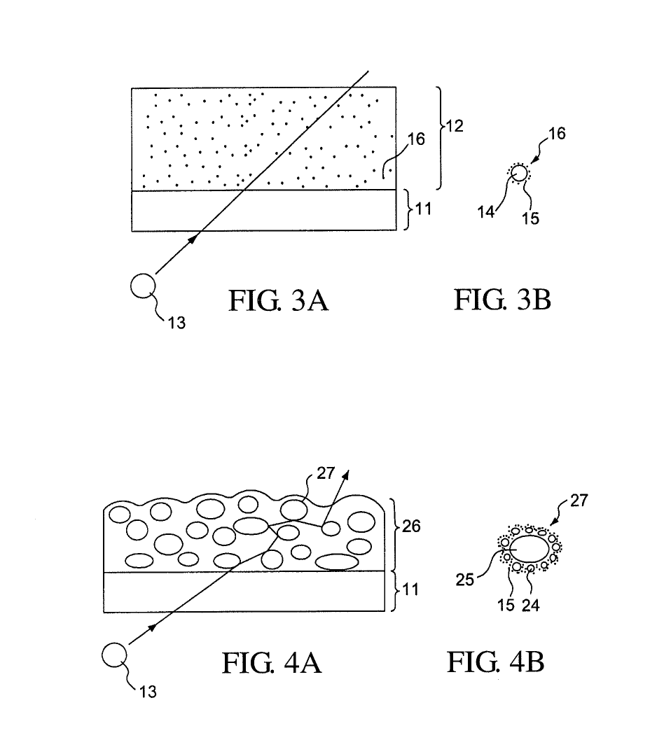

FIG. 1 is a preferred aspect of the present invention applied to the DSSC. A DSSC 1 according to the present invention mainly includes a first electrode 5, an electrolyte 9, and a second electrode 10. The first electrode is composed of a conductive substrate 2, a semiconductor material layer, and photosensitizers 8. The conductive substrate is composed of a substrate 3 and a conducting layer 4. The semiconductor material layer is only composed of a composite semiconductor material layer 7, and the photosensitizers are adsorbed on the surface of the composite semiconductor material.

FIG. 2 is another preferred aspect of the present invention applied to the DSSC. A DSSC 1 according to the present invention mainly includes a first electrode 5, an electrolyte 9, and a second electrode 10. The first electrode is composed of a conductive substrate 2, a semiconductor material layer, and photosensitizers 8. The conductive substrate is composed of a substrate 3 and a conducting layer 4. The semiconductor material layer is composed of a second semiconductor material layer 6 and a composite semiconductor material layer 7, with photosensitizers both adsorbed on surfaces of the composite semiconductor material and the second semiconductor material.

The species of the material serving as the substrate 3 of the present invention is not particularly limited, and can be, for example, but is not limited to, metal, such as an aluminum plate, a copper plate, a titanium plate, or a stainless steel plate; glass; or plastic, such as (but not limited to) polyester resin, polyacrylate resin, polystyrene resin, polyolefin resin, polycycloolefin resin, polyimide resin, polycarbonate resin, polyurethane resin, triacetyl cellulose (TAC), or polylactic acid; and any combination thereof. The above-mentioned substrate is needed to be plated with transparent conducting oxide (TCO) so as to form a conductive substrate 2. The conducting oxide can be, for example (but not limited to), fluorine-doped tin oxide (FTO), antimony-doped tin oxide (ATO), zinc oxide (ZnO), aluminum-doped zinc oxide (AZO), or indium tin oxide (ITO).

According to an embodiment of the present invention, a nanometer level semiconductor material is coated on the conductive substrate, so as to form a semiconductor material layer having a film thickness in a range from about 5 μm to about 20 μm. When the film thickness is lower than 5 μm, the performance of the DSSC is poor. When the film thickness is higher than 20 μm, the semiconductor material layer becomes crackable.

The photosensitizers 8 used in the DSSC according to the present invention may be any photosensitizers known by persons of ordinary skill in the art. For example, the photosensitizers can be selected from the group consisting of squaraine, chlorophyll, rhodamine, azobencene, cyanine, thiophene and metal complex (such as, but not limited to, Ru metal complex).

The electrolyte 9 used in the solar cell according to the present invention can be a liquid, colloid, or solid, which is well known by persons of ordinary skill in the art.

The second electrode 10 used in the solar cell according to the present invention includes a substrate and a conductor material coated or plated on the substrate. The material suitable for serving as the substrate can be selected from the materials suitable for serving as the substrate 3. The appropriate conductor material may be a carbon material, which is for example, but not limited to, carbon nanotube, carbon fiber, carbon nanohorn, carbon black, or Fullerene (C60, C70 Fullerene), or a combination of similar particles and conductive polymers; the conductive polymer can be, but is not limited to, polyanilines (PANs), polypyrroles (PPYs), poly-phenylene is vinylene (PPV), poly(p-phenylene)(PPP), polythiophene (PT), polyacetylene (PA), poly 3,4-ethylenedioxythiophene (PEDOT), or any combination thereof; or pure gold, pure platinum (Pt) or an alloy thereof.

The DSSC according to the present invention may be prepared by the method known by persons of ordinary skill in the art. The method, for example, includes the following steps:

(1) Uniformly apply a composite semiconductor material coating (having a surface area of 20 m²/g) onto an FTO glass substrate (having an area of about 0.7 cm×1.6 cm), so as to form a thin film having a thickness between about 11 and 12 μm, where the composite semiconductor material includes first semiconductor material particles (titanium oxide) (ST 41 (produced by ISK company, having a particle size of 100-300 nm, and a surface area of 6 m²/g)) and inorganic particulates (titanium oxide (HT (produced by Eternal company, having a particle size of 20-50 nm, and a surface area of 85 m²/g)));

(2) Sinter the TiO₂-containing FTO glass substrate under 400° C.-600° C., so as to form an electrode;

(3) Screen print platinum on another glass substrate, thus obtaining a second electrode having a platinum thickness of about 20 nm;

(4) Immense the electrode of Step (2) in an N719 produced by Solaronix company) photosensitizer solution (solvent: 1:1 n-butanol/acetonitrile) to adsorb photosensitizers for about 12-24 hours; and

(5) Inject an electrolyte solution (containing iodine (I₂), lithium iodide (LiI), 1-propyl-3-methyl-imidazolium iodide (PMII), and methylpyrrolidinone (MPN).

When the DSSC having the above structure is tested by using a light source (AM 1.5) simulating the solar light and having a light intensity (P) of 100 mW/cm², the obtained results are shown in the following Table 2. The AM 1.5 represents the Air Mass 1.5, in which AM=1/cos(θ), θ represents the angle relative to the vertical incident light. For the solar cell, an average illuminance of the US AM 1.5)(θ=48.2° is used as the average illuminance of the solar light on the ground (having a temperature of 25° C.), and the light intensity is about 100 mW/cm².

TABLE 2

| | | | | Short-Circuit | | |
|---|---|---|---|---|---|---|
| | | | Open Circuit | Current | | Photoelectric |
| Semiconductor material | | | Photovoltage | Density | | Conversion |
| (titanium oxide) | | | Voc^{a} | Jsc^{b} | Fill Factor | Efficiency |
| Layer | Composition | | (Voc) | (mA/cm²) | FF^{c} | η (%) |
| Multi- | HT | ST41:HT | 0.68 | 11.06 | 0.55 | 5.08 |
| layer | | (7:3) | | | | |
| | HT | Composite | 0.68 | 11.34 | 0.54 | 5.21 |
| | | Semiconductor | | | | |
| | | Material | | | | |

| | | | | | |
|---|---|---|---|---|---|
| Single- | ST41:HT | 0.64 | 10.36 | 0.63 | 4.18 |
| layer | (7:3) | | | | |
| | Composite | 0.62 | 11.28 | 0.66 | 4.62 |
| | Semiconductor | | | | |
| | Material | | | | |

^{a}The open circuit photovoltage (Voc) is a voltage measured when an external current of the solar cell is open.
^{b}The short-circuit current density (Jsc) is a quotient obtained by dividing an output current by an element area of the solar cell when the load is zero.
^{c}The fill factor (FF) is a ratio of an operating power output to a desired solar cell power output, and is an important parameter representing the performance of the solar cell.

It can be seen from Table 2 that as compared with the conventional semiconductor material, the DSSC fabricated by using the composite semiconductor materials according to the present invention achieves higher photoelectric conversion efficiency. To sum up, the composite semiconductor materials provided by the present invention achieve improved photoelectric conversion efficiency, and are industrially applicable.

1. A solar cell, comprising:
a first electrode, comprising a conductive substrate, a semiconductor material layer, and a photosensitizer;
an electrolyte; and
a second electrode,
wherein the semiconductor material layer comprises a composite semiconductor material layer, the composite semiconductor material layer comprising composite semiconductor materials, where the composite semiconductor materials comprise first semiconductor material particles and inorganic particulates on surfaces of the first semiconductor material particles, and the composite semiconductor materials have a surface area in a range from about 15 to about 80 m²/g.

2. The solar cell according to claim 1, wherein the composite semiconductor materials have a surface area in a range from about 20 to about 60 m²/g.

3. The solar cell according to claim 1, wherein the ratio of the particle size of the inorganic particulates to that of the first semiconductor material particles is not greater than ½.

4. The solar cell according to claim 1, wherein the first semiconductor material particles have a particle size in a range from 100 nanometers (nm) to 400 nm.

5. The solar cell according to claim 1, wherein the inorganic particulates have a particle size in a range from 5 nm to 50 nm.

6. The solar cell according to claim 1, wherein the semiconductor material layer further comprises a second semiconductor material layer, the second semiconductor material layer comprising second semiconductor materials that comprise second semiconductor material particles having a particle size in a range from 10 nm to 80 nm.

7. The solar cell according to claim 1, wherein the first semiconductor material particles are independently selected from the group consisting of titanium oxide, zinc oxide, tin oxide, zirconia, strontium titanate, silicon oxide, indium oxide, zinc sulfide, cadmium selenide, gallium phosphide, cadmium telluride, molybdenum selenide, tungsten selenide, niobium oxide, tungsten oxide, potassium tantalate, cadmium sulfide and any mixture thereof.

8. The solar cell according to claim 6, wherein the second semiconductor material particles are independently selected from the group consisting of titanium oxide, zinc oxide, tin oxide, zirconia, strontium titanate, silicon oxide, indium oxide, zinc sulfide, cadmium selenide, gallium phosphide, cadmium telluride, molybdenum selenide, tungsten selenide, niobium oxide, tungsten oxide, potassium tantalate, cadmium sulfide and any mixture thereof.

9. The solar cell according to claim 1, wherein the inorganic particulates are selected from the group consisting of titanium oxide, zinc oxide, tin oxide, zirconia, strontium titanate, silicon oxide, indium oxide, zinc sulfide, cadmium selenide, gallium phosphide, cadmium telluride, molybdenum selenide, tungsten selenide, niobium oxide, tungsten oxide, potassium tantalate, cadmium sulfide, calcium phosphate, calcium oxide and any mixture thereof.

10. The solar cell according to claim 1, wherein the first semiconductor material particles and the inorganic particulates are independently titanium oxide, zinc oxide or tin oxide.

11. The solar cell according to claim 6, wherein the second semiconductor material particles are titanium oxide, zinc oxide or tin oxide.

12. The solar cell according to claim 6, wherein the first semiconductor material particles and the inorganic particulates are independently titanium oxide, zinc oxide or tin oxide.
